(19) United States
(12) Patent Application Publication
(10) Pub. No.: US 2017/0187492 A1
(43) Pub. Date: Jun. 29, 2017

(54) FAULT TOLERANCE METHOD AND APPARATUS FOR MICROWAVE TRANSMISSION AND COMPUTER READABLE STORAGE MEDIUM

(71) Applicant: Sanechips Technology Co., Ltd., Shenzhen, Guangdong (CN)

(72) Inventor: Gang Feng, Shenzhen (CN)

(21) Appl. No.: 15/309,559

(22) PCT Filed: Oct. 9, 2014
(86) PCT No.: PCT/CN2014/088228

§ 371 Date: Nov. 8, 2016

(30) Foreign Application Priority Data
May 9, 2014 (CN) 201410195738.8

(51) Int. Cl. H04L 1/00; H03M 13/09; H04L 29/06

(52) U.S. Cl. CPC H04L 1/0061; H04L 69/22; H03M 13/09

(57) ABSTRACT

A fault tolerance method for microwave transmission is disclosed which includes arranging, by a receiving baseband device, a bitmap Cyclic Redundancy Check (CRC) code following a bitmap data in a timeslot data of a radio frame; and detecting the check result of the bitmap CRC code and processing the service data following the bitmap CRC code according to the check result. A fault tolerance apparatus for microwave transmission is also disclosed.

### TECHNICAL FIELD

The disclosure relates to the field of microwave transmission, and in particular to a fault tolerance method and apparatus for microwave transmission and a computer-readable storage medium.

### BACKGROUND

The majority of existing microwave transmission systems are error-bit-free peer-to-peer wireless communication systems. Conventional microwave systems forward data only when there are no error bits in output from a Low Density Parity Check (LDPC). By adopting such transmission method, the establishment of a link takes more time, although the bit error rate of the system is kept relatively low.

Moreover, in conventional microwave systems, the payload data included in the timeslot data in a radio frame is divided into Time Division Multiplexing (TDM) data unit and Media Access Control Protocol Data Unit (MAC PDU) which represents Ethernet (ETH) data. Moreover, the timeslot data also includes bitmap data for indicating the fragment structure of the TDM data. However, when the bitmap data is incorrect, the TDM data is affected, and besides, the packet header of an MAC PDU cannot be recognized accurately, and subsequently the fault is transferred in radio frames, making it impossible to transmit data normally.

### SUMMARY

To address existing technical problems, the embodiments of the disclosure mainly provides a fault tolerance method and apparatus for microwave transmission and a computer-readable storage medium.

The technical solutions of the disclosure are as follows.

A fault tolerance method for microwave transmission is provided which includes the following steps:

a receiving baseband device arranges a bitmap Cyclic Redundancy Check (CRC) code following a bitmap data in a timeslot data of a radio frame; and

the check result of the bitmap CRC code is detected and the service data following the bitmap CRC code is processed according to the check result.

In the foregoing solution, the length of the bitmap data is 1 byte, a value of the bitmap represents the fragment structure of the TDM data in the timeslot data; and

the arranged bitmap CRC code, which is 1 byte long, is used for checking the bitmap data.

In the foregoing solution, detecting the check result of the bitmap CRC code and processing the service data following the bitmap CRC code according to the check result includes: detecting the bitmap data and the bitmap CRC code, performing an operation on data composed of the bitmap data and the bitmap CRC code based on a principle of CRC to obtain a check result of the bitmap CRC code and, when the check result of the bitmap CRC code is ‘incorrect’, which indicates that the bitmap data is incorrect, processing the service data following the bitmap CRC code by taking all the service data as ETH data, and when the check result of the bitmap CRC code is ‘correct’, which indicates that the bitmap data is correct, forwarding the service data following the bitmap CRC code normally.

In the foregoing solution, processing the service data following the bitmap CRC code by taking all the service data as ETH data includes: when the check result of the bitmap CRC code is ‘incorrect’, the receiving baseband device takes the first 16-bit data following the bitmap CRC code as MAC header in MAC PDU and analyzes an MAC header to obtain the fragment information of the payload data in the MAC PDU; packets are assembled according to the fragment information of the payload data in each MAC PDU, the assembled packets are stored and reassembled, and the reassembled packets are output and checked.

In the foregoing solution, the MAC PDU includes an MAC header and payload data.

The length of the MAC header is 16 bits, including the first two bits for representing the fragment information of the payload data that indicates the fragment of an ETH packet the payload data belongs to, the fragment being a packet header, a packet body, a packet tail or a complete packet; eleven middle bits for representing the length of the payload data; and last three bits for representing another type of service to be transmitted through an ETH channel.

The maximum length of the payload data is 2048 bits.

In the foregoing solution, assembling packets according to the fragment information of the payload data in each MAC PDU includes: obtaining each fragment in an ETH packet according to the fragment information, forming the fragments into a complete ETH packet, and obtaining the packet length and the packet data of the ETH packet.

In the foregoing solution, storing and reassembling the assembled packets includes: storing the packet length and the packet data of the ETH packet in two First-In First-Out (FIFO) storage units, respectively; and reassembling, at outputs of the FIFO storage units, the data in the FIFO storage units according to the packet length and the packet data to obtain the complete ETH packet.

In the foregoing solution, outputting and checking the reassembled packets includes: outputting the reassembled ETH packets and performing the CRC on the ETH packet and, when the check result is ‘incorrect’, cleaning a result of analysis on the assembled packets, the data stored in the FIFO storage units and the data output, and detecting an MAC header of a packet header in an ETH packet in the next timeslot data to assemble packets.

A fault tolerance apparatus for microwave transmission is also provided which includes a check code arranging module and a processing module.

The check code arranging module is arranged to arrange a bitmap CRC code following a bitmap data in a timeslot data of a radio frame.

The processing module is arranged to detect a check result of the bitmap CRC code and process service data following the bitmap CRC code according to the check result.

In the foregoing solution, the bitmap CRC code, which is 1 byte long, is used for checking the bitmap data.

The bitmap data which is used to represent the fragment structure of the TDM data in the timeslot data is 1 byte long.

In the foregoing solution, the processing module includes: a CRC detection sub-module and a data processing sub-module.

The CRC detection sub-module is arranged to detect the bitmap data and the bitmap CRC code, perform an operation on data composed of the bitmap data and the bitmap CRC code based on a principle of CRC to obtain the check result of the bitmap CRC code.

The data processing sub-module is arranged to process the service data following the bitmap CRC code by taking all the service data as ETH data when the check result of the bitmap CRC code is ‘incorrect’, and to forward the service data following the bitmap CRC code normally when the check result of the bitmap CRC code is ‘correct’.

In the foregoing solution, the data processing sub-module is arranged to take the first 16-bit data following the bitmap CRC code as an MAC header in an MAC PDU and analyze the MAC header to obtain the fragment information of the payload data in the MAC PDU when the check result of the bitmap CRC code is ‘incorrect’, assemble packets according to the fragment information of the payload data in each MAC PDU, store and reassemble the assembled packets and output and check the reassembled packets.

In the foregoing solution, the MAC PDU includes an MAC header and payload data.

The length of the MAC header is 16 bits, including: the first two bits for representing the fragment information of the payload data that indicates the fragment of an ETH packet the payload data belongs to, the fragment being a packet header, a packet body, a packet tail or a complete packet; eleven middle bits for representing the length of the payload data; and last three bits for representing another type of service to be transmitted through an ETH channel.

The maximum length of the payload data is 2048 bits.

In the foregoing solution, the data processing sub-module is arranged to obtain each fragment in an ETH packet according to the fragment information when assembling packets according to the fragment information of the payload data in each MAC PDU, form the fragments into a complete ETH packet and obtain the packet length and the packet data of the ETH packet.

In the foregoing solution, the data processing sub-module is arranged to store, when storing and reassembling the assembled packets, the packet length and the packet data of the ETH packet in two First-In First-Out (FIFO) storage units, respectively, and reassemble, at the output end of the FIFO storage units, the data in the FIFO storage units according to the packet length and the packet data to obtain the complete ETH packet.

In the foregoing solution, the data processing sub-module is arranged to output the reassembled ETH packets and perform the CRC on the reassembled packet when outputting and checking the packet and, when the check result is ‘incorrect’, clean a result of analysis on the assembled packets, the data stored in the FIFO storage units and the data output, and detect the MAC header of the packet header in the ETH packet in the next timeslot data to assemble packets.

The disclosure further provides a computer-readable storage medium which contains a set of computer-executable instructions for executing the foregoing fault tolerance method for microwave transmission.

According to the fault tolerance method and apparatus for microwave transmission and the computer-readable storage medium provided herein, a receiving baseband device arranges a bitmap CRC code following a bitmap data in a timeslot data of a radio frame, detects the check result of the bitmap CRC code and processes the service data following the bitmap CRC code according to the check result. In this way, a link can be established as long as the key information of a radio frame in a microwave system is correct. Thus, the establishment time of a link can be significantly reduced. Furthermore, with the implementation of few redundancy checks, data loss can be minimized without causing the loss of correct TDM data or ETH data, and the ETH packet included in only one piece of incorrect timeslot data will be forwarded.

### BRIEF DESCRIPTION OF THE DRAWINGS

FIG. 1 is a schematic diagram illustrating a structure of a radio frame according to an embodiment of the disclosure;

FIG. 2 is a schematic diagram illustrating a structure of a piece of timeslot data included in existing radio frame;

FIG. 3 is a flow chart illustrating a process of a fault tolerance method for microwave transmission according to an embodiment of the disclosure;

FIG. 4 is a schematic diagram illustrating a structure of a piece of timeslot data with a bitmap CRC code according to an embodiment of the disclosure;

FIG. 5 is a schematic diagram illustrating a structure of an MAC header according to an embodiment of the disclosure;

FIG. 6 is a schematic diagram showing a state machine for realizing a solution provided herein, according to an embodiment of the disclosure;

FIG. 7 is a flow chart illustrating a procedure of processing ETH data according to an embodiment of the disclosure; and

FIG. 8 is a schematic diagram illustrating a structure of a fault tolerance apparatus for microwave transmission according to an embodiment of the disclosure.

### DETAILED DESCRIPTION

In embodiments of the disclosure, a receiving baseband device arranges a bitmap CRC code following a bitmap data in a timeslot data of a radio frame, detects the check result of the bitmap CRC code and processes the service data following the bitmap CRC code according to the check result.

The disclosure is described below in detail with reference to specific embodiments when read in conjunction with accompanying drawings.

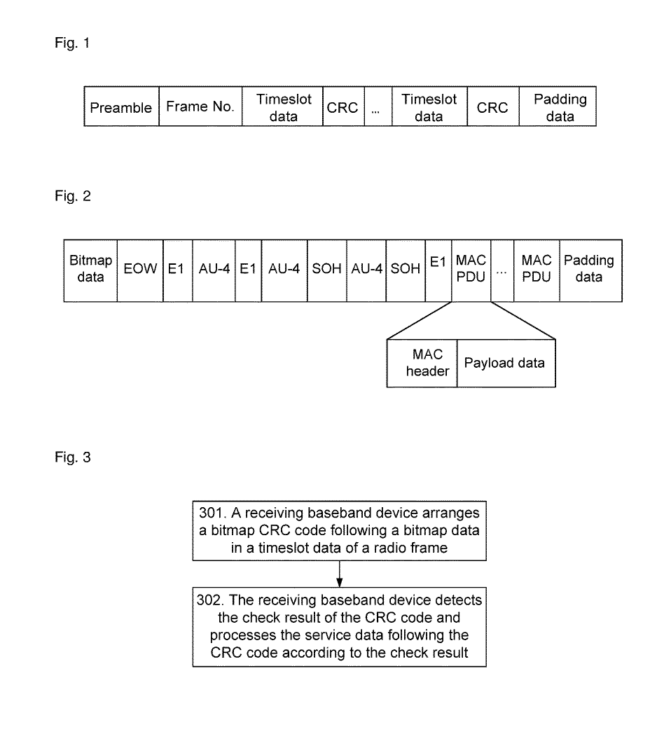

In the structure of the radio frame as shown in FIG. 1, the preamble and the frame No. at the head of a frame are is inserted by a receiving link. The key point of the method and apparatus provided herein lies in the timeslot data following the preamble and the frame No. A plurality of pieces of timeslot data are included in a radio frame. The timeslot data is followed by a CRC code. When the length of all data is less than length of a frame, padding data at the end of the frame is used to compensate the length of the frame.

FIG. 2 is a diagram showing a structure of existing timeslot data. As shown in FIG. 2, timeslot data is divided into TDM data and ETH data which is represented by MAC PDU. TDM data is divided into four types of data, i.e., EOW, E1, AU-4 and SOH. In a session service, EOW occupies a fixed bandwidth and is adapted to transmit TDM data using one of E1, AU-4 and SOU. The numbers of channels of E1, AU-4 or SOH that can be supported by the TDM data at most depend upon the configured transmission bandwidth. For example, when transmission bandwidth is 28 M, a system can support 75 channels of E1, 2 channels of AU-4s or 2 channels of SOH at most. The bitmap data indicates the specific channels of the TDM data that are successively transmitted in the current timeslot data. For example, if packets are transmitted in three channels of E1, that is, the first channel of E1, the third channel of E1 and the eighth channel of E1, in the current timeslot data, then the bitmap data is 10100001. The numeral ‘1’ represents fragments of E1, that is, the first E1 fragment is in the first channel of the data following, the second E1 fragment is in the third channel of the data following and the third E1 fragment is in the eighth channel of the data following. If there is remaining space in the timeslot data for transmitting data, in addition to TDM data, then the remaining space is used to transmit ETH data (represented by MAC PDU). MAC PDU is divided into an MAC header and payload data. There may be a plurality of MAC PDUs in a piece of timeslot data, and padding data is used to compensate the fixed length of a piece of timeslot data when the length of all data fails to reach the fixed length of the piece of timeslot data.

In a case where data is transmitted using the timeslot data structure as shown in FIG. 2, when bitmap data is incorrect, not only the TDM data but also the ETH data following is affected. For example, if correct bitmap data ‘10100001’, which means that the first, the third and the eighth channel of data is the TDM data, is changed to incorrect bitmap data ‘10100100’, which means that the first, the third and the sixth channel of data is TDM data, when being transmitted, the correctness of TDM data is reduced. Moreover, the ETH data following the TDM data cannot be recognized correctly. It is supposed to indicate that MAC PDU representing ETH is straight after the eighth channel of TDM data. However, it is now deemed by a receiving device that the MAC PUD is straight after the sixth channel of TDM data, and this error is transferred continuously, making it impossible to recover the correct transmission of data.

FIG. 3 is a flow chart illustrating a process of a fault tolerance method for microwave transmission according to an embodiment of the disclosure. As shown in FIG. 3, the fault tolerance method mainly includes the following steps.

In step 301, a receiving baseband device arranges a bitmap CRC code following a bitmap data in a timeslot data of a radio frame.

The length of the bitmap data is 1 byte, and a value of the bitmap represents the fragment structure of the TDM data in the timeslot data.

The length of the arranged bitmap CRC code is 1 byte long, is arranged to follow the bitmap data for checking the bitmap data.

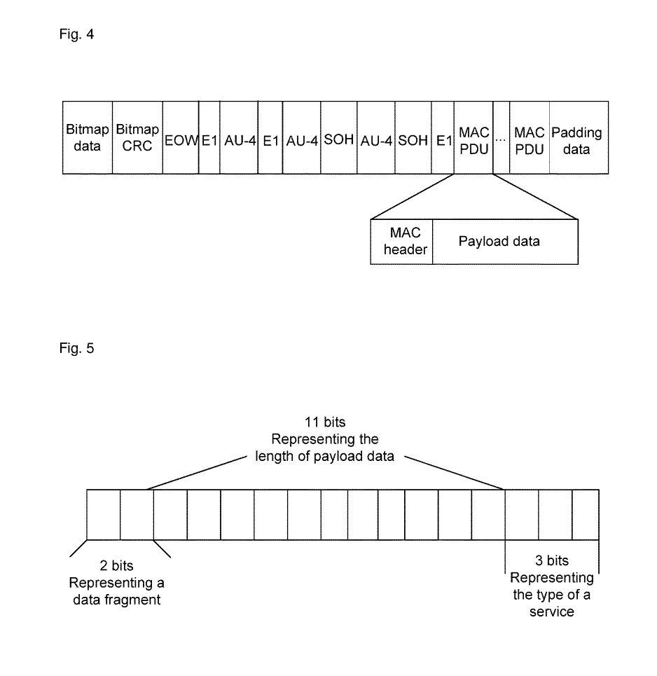

FIG. 4 is a schematic diagram illustrating a structure of a piece of timeslot data followed by the bitmap CRC code. Compared with the timeslot data as shown in FIG. 2, the timeslot datum as shown in FIG. 4 additionally includes a 1-byte CRC code for checking the correctness of bitmap data.

In step 302, the receiving baseband device detects the check result of the bitmap CRC code and processes the service data following the bitmap CRC code according to the check result.

Specifically, the bitmap data and the bitmap CRC code included in the timeslot data received are detected. An operation is performed on data composed of the bitmap data and the bitmap CRC code based on a principle of CRC to obtain the check result of the bitmap CRC code. When the check result of the bitmap CRC code is ‘incorrect’, which indicates that the bitmap data is incorrect, the service data following the bitmap CRC code is processed by taking all the service data as ETH data, no matter whether the service data following the bitmap CRC code is TDM data or MAC PDU. When the check result of the bitmap CRC code is ‘correct’, the service data following the bitmap CRC code is forwarded normally, that is, the service data following the bitmap CRC code is forwarded by using a data processing method that is corresponding to the type of the data following the bitmap CRC code.

A principle of CRC is specifically as follows: a generator polynomial is selected when a bitmap CRC code is arranged, the bitmap data is shifted left by 8 bits (shifted left by the number of the bits of a CRC code), the reminder resulting from the division of the left-shifted bitmap data by the generator polynomial using the module 2 division is a CRC code; if the reminder resulting from the division of the 16-bit data composed of the received bitmap data and the bitmap CRC code by the generator polynomial using the module 2 division is 0, then the result of the check is ‘correct’, otherwise, the result of the check is ‘incorrect’.

Processing the service data following the bitmap CRC code by taking all the service data as ETH data is implemented as follows. When the check result of the bitmap CRC code is ‘incorrect’, the first 16-bit data following the bitmap CRC code is taken as an MAC header in an MAC PDU and the MAC header is analyzed to obtain fragment information of a payload data in the MAC PDU. And packets are assembled according to the fragment information of the payload data in each MAC PDU. Then, the assembled packets are stored and reassembled, and the reassembled packets are outputted and checked.

As shown in FIGS. 2 and 4, the MAC PDU includes: an MAC header and payload data.

As shown in FIG. 5, the length of the MAC header is 16 bits, including: the first two bits for representing the fragment information of the payload data; eleven middle bits for representing the length of the payload data; and last three bits for representing another type of service to be transmitted through an ETH channel. The fragment information of the payload data indicates the fragment of an ETH packet the payload data belongs to, the fragment of an ETH packet may be a packet header, a packet body, a packet tail or a complete packet. For example, 00 represents that the payload data belongs to the packet header of an ETH packet, 01 represents that the payload data belongs to the packet body of an ETH packet, 10 represents that the payload data belongs to the packet tail of an ETH packet, and 11 represents the payload data belongs to a complete packet. For example, if the eleven middle bits of the MAC header is 00000001111, then the length of the payload data following the MAC header is 15 bits, that is, the 15-bit data following the MAC header is the payload data of the current MAC PDU.

Assembling packets according to the fragment information of the payload data in each MAC PDU is implemented as follows. Each fragment in an ETH packet is obtained according to the fragment information. And the fragments are formed into a complete ETH packet. Then, the packet length and the packet data of the ETH packet are obtained.

For example, the payload data in three different MAC PDUs separately constitutes the packet header, the packet body and the packet tail of an ETH packet, and a complete ETH packet can be formed by assembling the payload data in the three MAC PDUs. Alternatively, the packet header, the packet body and the packet tail of an ETH packet may be distributed in different MAC PDUs. Alternatively, an ETH packet may be born in a plurality of pieces of timeslot data, depending on specific circumstances.

Storing and reassembling the assembled packets is implemented as follows. The packet length and the packet data of the ETH packet are stored in two First-In First-Out (FIFO) storage units, respectively. And at the output end of the FIFO storage units, the data in the FIFO storage units is reassembled according to the packet length and the packet data to obtain the complete ETH packet.

Outputting and checking the reassembled packets is implemented as follows. The reassembled ETH packets are outputted, the CRC is performed on the reassembled ETH packet. When the check result is ‘incorrect’, a result of analysis on the assembled packets, the data stored in the FIFO storage units and the data output are cleaned, and the MAC header of the packet header of the ETH packet in the next timeslot data is detected to assemble packets. When the check result is ‘correct’, a result of analysis on the assembled packets, the data stored in the FIFO storage unit and the output data are remained.

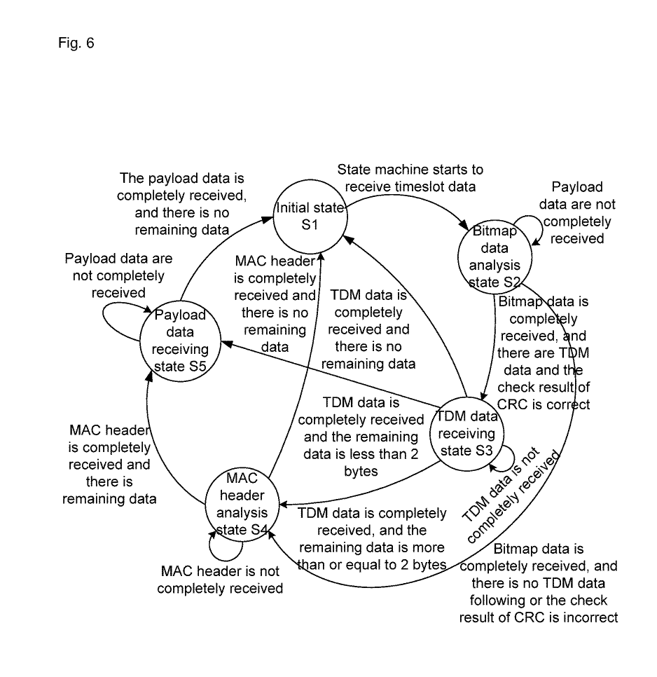

FIG. 6 is a schematic diagram showing a state machine for realizing the solutions provided in the embodiments of the disclosure. The state machine has five states, an initial state S1, a bitmap data analysis state S2, a TDM data receiving state S3, an MAC header analysis state S4 and a payload data receiving state S5.

The principle of the transfer of the state machine is as follows. The state machine initially stays in the initial state S1. When timeslot data arrives, the state machine switches to the bitmap data analysis state S2. In the state S2, the bitmap data in the timeslot data is received, until the bitmap data is completed received. The bitmap data is analyzed. When the result of the analysis indicates that there is no TDM data in the subsequent data or when the result of CRC is “incorrect”, the state machine switched to the MAC header analysis state S4. In the MAC header analysis state S4, the MAC header is analyzed. When MAC header data is all received and analyzed in the state S4 and no remaining data follows the received MAC header data, the state machine return to the initial state S1. When MAC header is all received and there is remaining data following the received MAC header, the state machine enters the payload data receiving state S5. In the payload data receiving state S5, the payload data is received until there is no remaining data following the payload data, then the state machine return to the initial state S1.

If it is known from the analysis of the bitmap data received in the state S2 that there are following TDM data and the check result of bitmap CRC is ‘correct’, the state machine switches to the TDM data receiving state S3. TDM data is received in the state S3. After the TDM data is received and no remaining data follows the TDM data received, the state machine switches back to the initial state S1. When the TDM data is received and the length of the remaining data following the TDM data received is less than 2 bytes (shorter than one 2-byte MAC header), the state machine switched to the payload data receiving state S5. When the TDM data is received and the length of the remaining data following the TDM data received is greater than or equal to 2 bytes, the state machine switches to the MAC header analysis state S4. The MAC header data is analyzed in the state S4. When the MAC header data is all received and no remaining data follows the MAC header data, the state machine switches back to the initial state S1. When the MAC header data is all received and there is remaining data following the MAC header data, the state machine switches to the payload data receiving state S5.

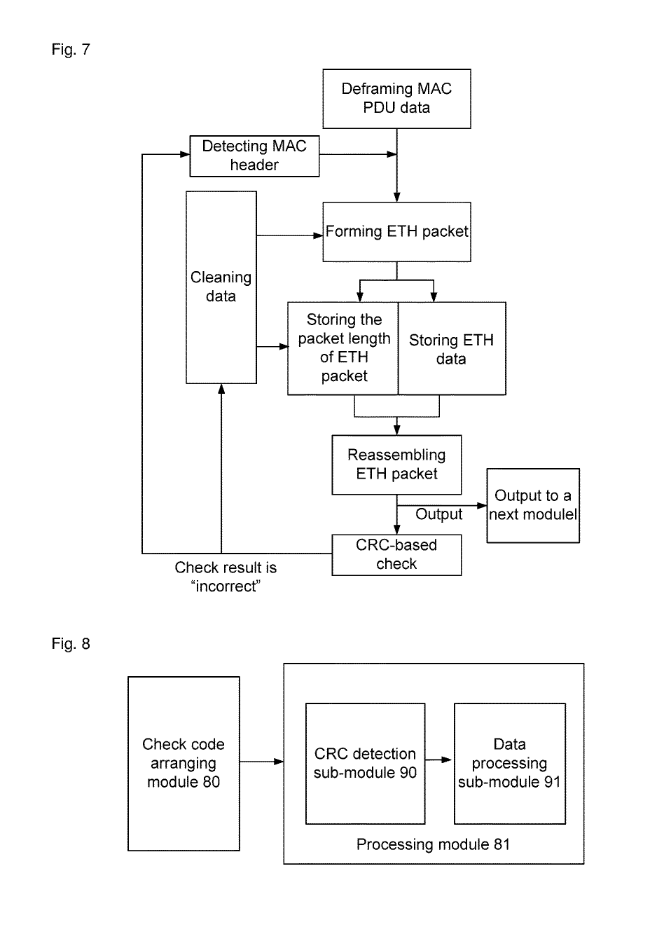

FIG. 7 is a flow chart illustrating a procedure of processing ETH data. Specifically, the processing flow is as follows. MAC PDU data is deframed at a former level. A packing analysis is performed on the deframed PDU data to obtain an ETH packet. The packet length of the ETH packet is determined according to the packet header and the packet tail of the ETH packet. The packet length and ETH data are stored in different FIFO storage units, respectively. As shown in FIG. 7, a first FIFO storage unit is arranged to store ETH data, and a second FIFO storage unit is arranged to store the packet length of an ETH packet. The ETH packet is reassembled and checked at the output end of the FIFO storage units. That is, data is acquired from the first FIFO storage unit according to the packet length stored in the second FIFO storage unit to form a complete ETH packet. The ETH packet is output to a module of the next level which is located in a device on a data link layer and which is a different device in a level different from that of the foregoing receiving baseband device on a transmission layer. Meanwhile, the ETH packet is checked using the CRC code carried in the ETH packet. When the check result is ‘incorrect’, the ETH packet resulting from a data packing analysis and the data stored in the FIFO storage units are cleaned, the output data is cleaned immediately. The MAC header of the packet header of the ETH packet included in the next timeslot data is detected to assemble packets. Cleaning of the output data is implemented by changing all the output from the output port of the receiving baseband device to 0.

FIG. 8 is a diagram showing a structure of a fault tolerance apparatus for microwave transmission according to an embodiment of the disclosure. The fault tolerance apparatus includes a check code arranging module 80 and a processing module 81.

The check code arranging module 80 is arranged to arrange a bitmap CRC code following a bitmap data in a timeslot data of a radio frame.

The processing module 81 is arranged to detect a check result of the bitmap CRC code and process service data following the bitmap CRC code according to the check result.

The length of the bitmap data is 1 byte long, and the bitmap data represents the fragment structure of the TDM data included in the timeslot data.

The length of the bitmap CRC code is 1 byte long, and the bitmap data is used for checking the bitmap data.

The processing module 81 includes a CRC detection sub-module 90 and a data processing sub-module 91.

The CRC detection sub-module 90 is arranged to detect the bitmap data and the bitmap CRC code and perform an operation on data composed of the bitmap data and the bitmap CRC code based on a principle of CRC to obtain the check result of the bitmap CRC code.

The data processing sub-module 91 is arranged to process the service data following the bitmap CRC code by taking all the service data as ETH data when the check result of the bitmap CRC code is ‘incorrect’, and to forward the service data following the bitmap CRC code normally when the check result of the bitmap CRC code is ‘correct’.

The data processing sub-module 91 is arranged to take the first 16-bit data following the bitmap CRC code as a Media Access Control Protocol (MAC) header in a Media

Access Control Protocol Data Unit (MAC PDU) and analyze the MAC header to obtain fragment information of payload data in the MAC PDU, when the check result of the bitmap CRC code is ‘incorrect’; assemble packets according to the fragment information of the payload data in each MAC PDU, store and reassemble the packets, and output and check the reassembled packets; and to forward the service data following the bitmap CRC code normally when the check result of the bitmap CRC code is ‘correct’.

The MAC PDU includes: an MAC header and payload data.

The length of the MAC header is 16 bits, including: the first two bits for representing the fragment information of the payload data that indicates the fragment of an ETH packet the payload data belongs to, the fragment is a packet header, a packet body, a packet tail or a complete packet; eleven middle bits for representing the length of the payload data; and last three bits for representing another type of service to be transmitted through an ETH channel.

The maximum length of the payload data is 2048 bits.

The data processing sub-module 91 is arranged to obtain, when assembling packets according to the fragment information of the payload data in each MAC PDU, each fragment in an ETH packet according to the fragment information, form the fragments into a complete ETH packet and obtain the packet length and the packet data of the ETH packet.

The data processing sub-module stores the packet length and the packet data of the ETH packet in two FIFO storage units, respectively when storing and reassembling the assembled packets; and reassemble, at the output end of the FIFO storage units, the data stored in the FIFO storage units according to the packet length and the packet data to obtain the complete ETH packet.

The data processing sub-module 91 is arranged to output the reassembled ETH packets and perform the CRC on the ETH packet when outputting and checking the reassembled ETH packets and, when the check result is ‘incorrect’, clean the result of the analysis on the packets, the data stored in the FIFO storage units and the data output, and detect the MAC header of the packet header of the ETH packet in the next timeslot data to assemble packets.

The check code arranging module 80 may be implemented as a chip with a simple operation implementation capability, for example, a singlechip, that is located in a device, or a main processing chip.

The processing module 81 may be made up of the main processing chip of a receiving baseband device and the peripheral circuits thereof, for example, an FPGA and peripheral circuits thereof.

The disclosure further provides a computer-readable storage medium which contains a set of computer-executable instructions for executing the foregoing fault tolerance method for microwave transmission.

The fault tolerance method for microwave transmission provided herein, if implemented as a software function module and sold or used as an independent product, can be stored in a computer-readable storage medium. It should be appreciated by those skilled in the art that the embodiments of the disclosure can be provided as methods, systems or computer program products. Thus, the disclosure can be embodied as pure hardware embodiments, pure software embodiments or the combinations of hardware embodiments and software embodiments. Moreover, the disclosure may be embodied in the form of a computer program product implemented on one or more computer-usable storage medium, including, but not limited to, Universal Serial Bus (USB) drive, removable hard disk drive, Read-Only Memory (ROM), disk memory, CD-ROM and optical memory, on which computer-readable program codes are stored.

In the embodiments of the disclosure, a bitmap CRC code following a bitmap data in a timeslot data of a radio frame is arranged, the check result of the bitmap CRC code is detected, and the service data following the bitmap CRC code is processed according to the check result, such that the establishment time of a link during the process of microwave transmission is reduced. Moreover, due to the arranged bitmap CRC code, only one ETH packet is forwarded when certain bitmap data of radio frame data is incorrect. Thus, the error is not transferred continuously to disenable the recovery of the normal transmission of data.

Although preferred embodiments of the disclosure are illustrated above, the preferred embodiments are not to be construed as limiting the protection scope of the disclosure, and any modification, substitute or improvement devised without departing from the spirit and scope of the present invention should fall within the protection scope of the disclosure.

1. A fault tolerance method for microwave transmission, comprising:
arranging, by a receiving baseband device, a bitmap Cyclic Redundancy Check (CRC) code following a bitmap data in a timeslot data of a radio frame; and
detecting a check result of the bitmap CRC code and processing a service data following the bitmap CRC code according to the check result.

2. The fault tolerance method according to claim 1, wherein a length of the bitmap data is 1 byte, and a value of the bitmap represents a fragment structure of a Time Division Multiplexing (TDM) data in the timeslot data; and
the arranged bitmap CRC code, which is 1 byte long, is used for checking the bitmap data.

3. The fault tolerance method according to claim 1, wherein detecting the check result of the bitmap CRC code and processing the service data following the bitmap CRC code according to the check result comprises:
detecting the bitmap data and the bitmap CRC code, performing an operation on data composed of the bitmap data and the bitmap CRC code based on a principle of CRC to obtain the check result of the bitmap CRC code and, when the check result of the bitmap CRC code is ‘incorrect’, which indicates that the bitmap data is incorrect, processing the service data following the bitmap CRC code by taking all the service data as Ethernet (ETH) data, and when the check result of the bitmap CRC code is ‘correct’, which indicates that that the bitmap data is correct, forwarding the service data following the bitmap CRC code normally.

4. The fault tolerance method according to claim 3, wherein processing the service data following the bitmap CRC code by taking all the service data as ETH data comprises:
when the check result of the bitmap CRC code is ‘incorrect’, taking, by the receiving baseband device, the first 16-bit data following the bitmap CRC code as a Media Access Control (MAC) header in a Media Access Control Protocol Data Unit (MAC PDU) and analyzing the MAC header to obtain fragment information of a payload data in the MAC PDU; assembling packets according to the fragment information of the payload data in each MAC PDU, storing the assembled packets and reassembling the packets, and outputting and checking the reassembled packets.

5. The fault tolerance method according to claim 4, wherein the MAC PDU includes: an MAC header and payload data, wherein
the length of the MAC header is 16 bits, including: the first two bits for representing the fragment information of the payload data that indicates the fragment of an ETH packet the payload data belongs to, the fragment being a packet header, a packet body, a packet tail or a complete packet; eleven middle bits for representing the length of the payload data; and last three bits for representing another type of service to be transmitted through an ETH channel; and
a maximum length of the payload data is 2048 bits.

6. The fault tolerance method according to claim 5, wherein assembling packets according to the fragment information of the payload data in each MAC PDU comprises: obtaining each fragment in an ETH packet according to the fragment information, forming the fragments into a complete ETH packet, and obtaining the packet length and the packet data of the ETH packet.

7. The fault tolerance method according to claim 6, wherein storing and reassembling the assembled packets comprises: storing the packet length and the packet data of the ETH packet in two First-In First-Out (FIFO) storage units, respectively; and reassembling, at outputs of the FIFO storage units, the data in the FIFO storage units according to the packet length and the packet data to obtain the complete ETH packet.

8. The fault tolerance method according to claim 7, wherein outputting and checking the reassembled packets comprises: outputting the reassembled ETH packets and performing the CRC on the reassembled ETH packets and when the check result is ‘incorrect’, cleaning a result of analysis on the assembled packets, the data stored in the FIFO storage units and the data output, and detecting an MAC header of a packet header in an ETH packet in the next timeslot data to assemble packets.

9. A fault tolerance apparatus for microwave transmission, comprising:
a memory storing processor-executable instructions; and
a processor arranged to execute the stored processor-executable instructions to perform steps of:
arranging a bitmap Cyclic Redundancy Check (CRC) code following a bitmap data in a timeslot data of a radio frame; and
detecting a check result of the bitmap CRC code and processing service data following the bitmap CRC code according to the check result.

10. The fault tolerance apparatus according to claim 9, wherein the bitmap CRC code, which is 1 byte long, is used for checking the bitmap data; and
the bitmap data is used to represent a fragment structure of Time Division Multiplexing (TDM) data in the timeslot data, and is 1 byte long.

11. The fault tolerance apparatus according to claim 9, wherein when detecting the check result of the bitmap CRC code and processing the service data following the bitmap CRC code according to the check result comprises, the processor is arranged to execute the stored processor-executable instructions to perform steps of:
detecting the bitmap data and the bitmap CRC code and performing an operation on data composed of the bitmap data and the bitmap CRC code based on a principle of CRC to obtain the check result of the bitmap CRC code; and
processing the service data following the bitmap CRC code by taking all the service data as Ethernet (ETH) data when the check result of the bitmap CRC code is ‘incorrect’, and forwarding the service data following the bitmap CRC code normally when the check result of the bitmap CRC code is ‘correct’.

12. The fault tolerance apparatus according to claim 11, wherein when processing the service data following the bitmap CRC code by taking all the service data as ETH data, the processor is arranged to execute the stored processor-executable instructions to perform steps of:
taking the first 16-bit data following the bitmap CRC code as a Media Access Control Protocol (MAC) header in a Media Access Control Protocol Data Unit (MAC PDU) and analyzing the MAC header to obtain fragment information of payload data in the MAC PDU, when the check result of the bitmap CRC code is ‘incorrect’; assembling packets according to the fragment information of the payload data in each MAC PDU, storing and reassembling the packets, and outputting and checking the reassembled packets.

13. The fault tolerance apparatus according to claim 12, wherein the MAC PDU includes: an MAC header and payload data, wherein
the length of the MAC header is 16 bits, including: the first two bits for representing the fragment information of the payload data that indicates the fragment of an ETH packet the payload data belongs to, the fragment being a packet header, a packet body, a packet tail or a complete packet; eleven middle bits for representing the length of the payload data; and last three bits for representing another type of service to be transmitted through an ETH channel; and
a maximum length of the payload data is 2048 bits.

14. The fault tolerance apparatus according to claim 13, wherein when assembling packets according to the fragment information of the payload data in each MAC PDU, the processor is arranged to execute the stored processor-executable instructions to perform steps of:
obtaining each fragment in an ETH packet according to the fragment information, forming the fragments into a complete ETH packet and obtaining the packet length and the packet data of the ETH packet.

15. The fault tolerance apparatus according to claim 14, wherein when storing and reassembling the assembled packets, the processor is arranged to execute the stored processor-executable instructions to perform steps of:
storing the packet length and the packet data of the ETH packet in two First-In First-Out (FIFO) storage units, respectively, and reassembling, at outputs of the FIFO storage units, the data in the FIFO storage units according to the packet length and the packet data to obtain the complete ETH packet.

16. The fault tolerance apparatus according to claim 15, wherein when outputting and checking the reassembled packets, the processor is arranged to execute the stored processor-executable instructions to perform steps of:
outputting the reassembled ETH packets and performing the CRC on the reassembled ETH packet; and, when the check result is ‘incorrect’, cleaning a result of analysis on the assembled packets, the data stored in the FIFO storage units and the data output, and detecting an MAC header of a packet header in an ETH packet in the next timeslot data to assemble packets.

17. A non-transitory computer-readable storage medium containing a set of computer-executable instructions for executing a fault tolerance method for microwave transmission comprising:
arranging, by a receiving baseband device, a bitmap Cyclic Redundancy Check (CRC) code following a bitmap data in a timeslot data of a radio frame; and
detecting a check result of the bitmap CRC code and processing a service data following the bitmap CRC code according to the check result.
